(19) United States
(12) Patent Application Publication
(10) Pub. No.: US 2023/0060999 A1
(43) Pub. Date: Mar. 2, 2023

(54) POLISHING COMPOSITIONS AND METHODS OF USING THE SAME

(71) Applicant: FUJIFILM ELECTRONIC MATERIALS U.S.A., INC., North Kingstown, RI (US)

(72) Inventors: James McDonough, Gilbert, AZ (US); Bin Hu, Chandler, AZ (US); Qingmin Cheng, Mesa, AZ (US)

(73) Assignee: FUJIFILM ELECTRONIC MATERIALS U.S.A., INC., North Kingstown, RI (US)

(21) Appl. No.: 17/896,259

(22) Filed: Aug. 26, 2022

Related U.S. Application Data
(60) Provisional application No. 63/239,657, filed on Sep. 1, 2021.

(51) Int. Cl. C09G 1/02; H01L 21/321

(52) U.S. Cl. CPC C09G 1/02; H01L 21/3212

(57) ABSTRACT

The present disclosure provides a polishing composition that includes at least one first amine, at least one second amine, and other components such as azoles. The first amine has a low molecular weight, for example 120 g/mol or less. The second amine has a high molecular weight, for example 125 g/mol or higher. The compositions can polish substrates that include copper and molybdenum, or alloys of each, at a high selectivity of copper to molybdenum.

### CROSS REFERENCE TO RELATED APPLICATION

The present application claims the benefit under 35 U.S.C. §119 of U.S. Provisional Pat. Application Serial No. 63/239,657, filed on Sep. 1, 2021, which is herein incorporated by reference.

### BACKGROUND OF THE DISCLOSURE

### 1. Field of the Disclosure

The present disclosure relates to chemical mechanical polishing compositions for the semiconductor industry. In particular, the present disclosure relates to compositions that are particularly beneficial for polishing substrates that include copper and molybdenum, and alloys thereof.

### 2. Discussion of the Related Art

The semiconductor industry is continually driven to improve chip performance by further miniaturization of devices through process and integration innovations. Chemical Mechanical Polishing/Planarization (CMP) is a powerful technology as it makes many complex integration schemes at the transistor level possible, thereby facilitating increased chip density.

CMP is a process used to planarize/flatten a wafer surface by removing material using abrasion-based physical processes concurrently with surface-based chemical reactions. In general, a CMP process involves applying a CMP polishing composition (e.g., an aqueous chemical formulation) to a wafer surface while contacting the wafer surface with a polishing pad and moving the polishing pad in relation to the wafer. Polishing compositions typically include an abrasive component and dissolved chemical components, which can vary significantly depending upon the materials (e.g., metals, metal oxides, metal nitrides, dielectric materials such as silicon oxide and silicon nitride, etc.) present on the wafer that will be interacting with the polishing composition and the polishing pad during the CMP process.

Molybdenum is a transition metal with very low chemical reactivity, high hardness, great conductivity, strong wear resistance, and high corrosion-resistance. Molybdenum can also form heteropoly and alloy compounds with other elements. With respect to its use in the microelectronic industry, molybdenum and alloys thereof may find use as interconnects, diffusion barriers, photo masks, and plug filling materials. However, because of its hardness, susceptibility to corrosion in alkaline pH, and chemical resistance, molybdenum is difficult to polish at a high removal rate and with low defectivity, which presents a challenge for CMP of molybdenum containing substrates.

### SUMMARY OF THE DISCLOSURE

This summary is provided to introduce a selection of concepts that are further described below in the detailed description. This summary is not intended to identify key or essential features of the claimed subject matter, nor is it intended to be used as an aid in limiting the scope of the claimed subject matter.

This disclosure is based on the unexpected discovery that certain polishing compositions can selectively remove copper (Cu) and/or its alloys relative to other materials (e.g., molybdenum) in a semiconductor substrate during a CMP process in a controlled manner with an excellent corrosion resistance.

In one aspect, this disclosure features polishing compositions that include: at least one abrasive; at least one azole compound; at least one first amine compound, the at least one first amine compound comprising an amino acid having a molecular weight of at most 120 g/mol; at least one second amine compound having a molecular weight of at least 125 g/mol; and an aqueous solvent. The present disclosure also provides a method for polishing a substrate containing at least one of copper, alloys of copper, molybdenum, and alloys of molybdenum.

In yet another aspect, this disclosure features methods that includes applying the previously discussed polishing composition to a substrate comprising at least one of copper, molybdenum, an alloy of copper, an alloy of molybdenum, and any combinations thereof, on a surface of the substrate; and bringing a pad into contact with the surface of the substrate and moving the pad in relation to the substrate.

### BRIEF DESCRIPTION OF THE DRAWINGS

FIG. 1 is a schematic drawing of a substrate that can be polished by the compositions of the present disclosure.

### DETAILED DESCRIPTION OF THE DISCLOSURE

The present disclosure relates to polishing compositions and methods for polishing semiconductor substrates using the same. In some embodiments, this disclosure relates to polishing compositions used for polishing substrates that include at least one portion containing copper (Cu), and at least one portion containing molybdenum (Mo) metal. The substrates may also, or alternatively, include alloys of copper and/or alloys of molybdenum. While copper has been widely used as a conductive component in semiconductor substrates for a long time, molybdenum is a relatively new and lightly utilized material in semiconductor manufacturing. One area where molybdenum has the potential for being productively used in a semiconductor device is as a liner material that can effectively separate copper from a dielectric material. However, conventional polishing compositions that are in use for copper have been found to be incompatible with molybdenum. For example, they cause high Mo removal rates and corrosion, including galvanic corrosion.

The present disclosure has unexpectedly found that a combination of two amine compounds, one with a higher molecular weight (e.g. greater than 125 g/mol) and one that is an amino acid with a low molecular weight (e.g. lower than 120 g/mol), is synergistic when polishing substrates that include both copper and molybdenum. Without being bound by theory, it is believed that the low molecular weight amino acid works as a copper removal rate enhancer, and the amine compound with the higher molecular weight works well to suppress molybdenum removal and corrosion. The selectivity in removal rate ratios between copper and molybdenum could not have been predicted based on how the amine compounds perform individually.

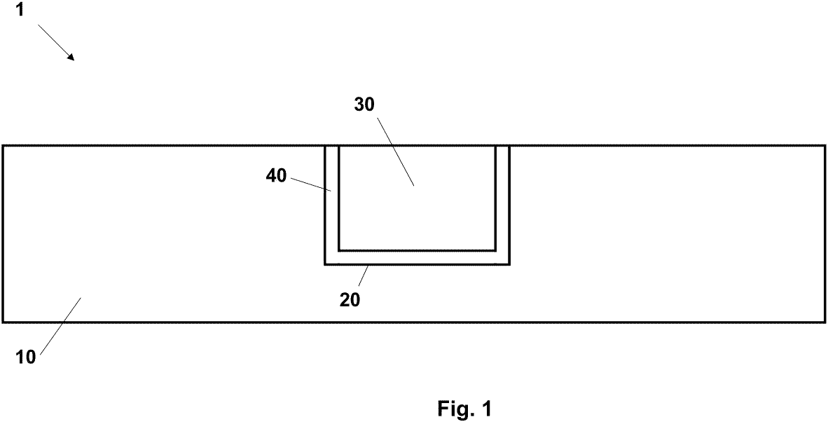

One non-limiting example of a substrate that can be polished by the compositions of the present disclosure is shown schematically in FIG. 1. Substrate 1 has a layer of non-conducting material 10 (e.g., a dielectric material) with a trench 20 therein. A copper layer or material 30 is in trench 20. In some applications, it is desirable to include a liner 40 in trench 20, to isolate copper layer 30 from the non-conducting material. The liner 40 can help prevent migration of copper electrons from copper layer 30 to non-conducting material 10. Molybdenum is increasingly looked to as a material for liner 40. When fabricating substrate 1, an overburden of copper may be applied to ensure proper fill of trench 20. Thus, during polishing, the composition may initially be removing mostly copper, before starting to remove the material of liner 40, e.g. molybdenum, when it becomes exposed during the polishing process.

In one or more embodiments, a polishing composition described herein can include at least one abrasive, at least one azole compound, at least one first amine compound, the at least one first amine compound comprising an amino acid having a molecular weight of at most 120 g/mol, at least one second amine compound having a molecular weight of at least 125 g/mol, and an aqueous solvent. In one or more embodiments, a polishing composition according to the present disclosure can include from about 0.01% to about 50% by weight of at least one abrasive, from about 0.001% to about 10% by weight of at least one azole compound, from about 0.001% to about 18% by weight of at least one first amine compound, from about 0.001% to about 18% at least one second amine compound, and the remaining percent by weight (e.g., from about 10% to about 99.99% by weight) of an aqueous solvent (e.g., deionized water).

In one or more embodiments, the present disclosure provides a concentrated polishing composition that can be diluted with water prior to use by up to a factor of two, or up to a factor of four, or up to a factor of six, or up to a factor of eight, or up to a factor of ten, or up to a factor of 15, or up to a factor of 20. In other embodiments, the present disclosure provides a point-of-use (POU) polishing composition, comprising the above-described polishing composition, water, and optionally an oxidizer.

In one or more embodiments, a POU polishing composition can include from about 0.01% to about 25% by weight of at least one abrasive, from about 0.001% to about 1% by weight of at least one azole compound, from about 0.001% to about 8% by weight of at least one first amine compound, from about 0.001% to about 8% by weight of at least one second amine compound, and the remaining percent by weight (e.g., from about 59% to about 99.99% by weight) of an aqueous solvent (e.g., deionized water).

In one or more embodiments, a concentrated polishing composition can include from 0.02% to about 50% by weight of at least one abrasive, from about 0.01% to about 10% by weight of at least one azole compound, from about 0.01% to about 18% by weight of at least one first amine compound, from about 0.01% to about 18% by weight of at least one second amine compound, and the remaining percent by weight (e.g., from about 4% to about 99.98% by weight) of an aqueous solvent (e.g., deionized water).

In one or more embodiments, the polishing compositions described herein can include at least one (e.g., two or three) abrasive. In one or more embodiments, the at least one abrasive is selected from the group consisting of cationic abrasives, substantially neutral abrasives, and anionic abrasives. In one or more embodiments, the at least one abrasive is selected from the group consisting of alumina, silica, titania, ceria, zirconia, co-formed products thereof (i.e., co-formed products of alumina, silica, titania, ceria, or zirconia), coated abrasives, surface modified abrasives, and mixtures thereof. In some embodiments, the at least one abrasive does not include ceria. In some embodiments, the at least one abrasive has a high purity, and can have less than about 100 ppm of alcohol, less than about 100 ppm of ammonia, and less than about 100 ppb of an alkali cation such as sodium cation. The abrasive can be present in an amount of from about 0.01% to about 12% (e.g., from about 0.5% to about 10%), based on the total weight of a POU polishing composition, or any subranges thereof.

In one or more embodiments, the abrasive is a silica-based abrasive, such as one selected from the group consisting of colloidal silica, fumed silica, and mixtures thereof. In one or more embodiments, the abrasive can be surface modified with organic groups and/or non-siliceous inorganic groups. For example, the cationic abrasive can include terminal groups of formula (I):

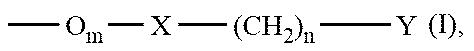

in which m is an integer from 1 to 3; n is an integer from 1 to 10; X is Al, Si, Ti, Ce, or Zr; and Y is a cationic amino or thiol group. As another example, the anionic abrasive can include terminal groups of formula (I):

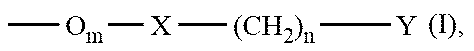

in which m is an integer from 1 to 3; n is an integer from 1 to 10; X is Al, Si, Ti, Ce, or Zr; and Y is an acid group.

In one or more embodiments, the abrasive described herein can have a mean particle size of from at least about 1 nm (e.g., at least about 5 nm, at least about 10 nm, at least about 20 nm, at least about 40 nm, at least about 50 nm, at least about 60 nm, at least about 80 nm, or at least about 100 nm) to at most about 1000 nm (e.g., at most about 800 nm, at most about 600 nm, at most about 500 nm, at most about 400 nm, at most about 200 nm, or at most about 150 nm). As used herein, the mean particle size (MPS) is determined by dynamic light scattering techniques. In one or more embodiments, the abrasive can be particles of a single chemical species (e.g., silica particles) and the polishing composition may not include abrasives that are composites of two or more materials (e.g., silica particles embedded in a ceramic matrix).

In one or more embodiments, the at least one abrasive is in an amount of from at least about 0.01% (e.g., at least about 0.05%, at least about 0.1%, at least about 0.2%, at least about 0.4%, at least about 0.5%, at least about 0.6%, at least about 0.8%, at least about 1%, at least about 1.2%, at least about 1.5%, at least about 1.8%, or at least about 2%) by weight to at most about 50% (e.g., at most about 45%, at most about 40%, at most about 35%, at most about 30%, at most about 25%, at most about 20%, at most about 15%, at most about 12%, at most about 10%, at most about 5%, at most about 4%, at most about 3%, at most about 2%, at most about 1%) by weight of the polishing compositions described herein.

In one or more embodiments, the polishing compositions described herein include at least one (e.g., two or three) azole compounds. The azole compound is not particularly limited, but specific examples thereof include heterocyclic azoles, substituted or unsubstituted triazoles (e.g., benzotriazoles), substituted or unsubstituted tetrazoles, substituted or unsubstituted diazoles (e.g., imidazoles, benzimidazoles, thiadiazoles, and pyrazoles), and substituted or unsubstituted benzothiazoles. Herein, a substituted diazole, triazole, or tetrazole refers to a product obtained by substitution of one or two or more hydrogen atoms in the diazole, triazole, or tetrazole with, for example, a carboxyl group, an alkyl group (e.g., a methyl, ethyl, propyl, butyl, pentyl, or hexyl group), a halogen group (e.g., F, Cl, Br, or I), an amino group, or a hydroxyl group. In one or more embodiments, the azole is selected from the group consisting of tetrazole, benzotriazole, tolyltriazole, methyl benzotriazole (e.g., 1-methyl benzotriazole, 4-methyl benzotriazole, and 5-methyl benzotriazole), ethyl benzotriazole (e.g., 1-ethyl benzotriazole), propyl benzotriazole (e.g., 1-propyl benzotriazole), butyl benzotriazole (e.g., 1-butyl benzotriazole and 5-butyl benzotriazole), pentyl benzotriazole (e.g., 1-pentyl benzotriazole), hexyl benzotriazole (e.g., 1-hexyl benzotriazole and 5-hexyl benzotriazole), 5,6-dimethyl benzotriazole, chloro benzotriazole (e.g., 5-chloro benzotriazole), 5,6-dichloro benzotriazole, 1-(chloromethyl)-1-H-benzotriazole, chloroethyl benzotriazole, phenyl benzotriazole, benzyl benzotriazole, aminotriazole, aminobenzimidazole, pyrazole, imidazole, aminotetrazole, adenine, benzimidazole, thiabendazole, 1,2,3-triazole, 1,2,4-triazole, 1-hydroxybenzotriazole, 2-methylbenzothiazole, 2-aminobenzimidazole, 2-amino-5-ethyl-1,3,4-thiadiazole, 3,5-diamino-1,2,4-triazole, 3-amino-5-methylpyrazole, 4-amino-4H-1,2,4-triazole, and combinations thereof. Without wishing to be bound by theory, it is believed that the azole compound (such as those described above) can be used as an effective copper corrosion inhibitor in the polishing compositions described herein to improve the corrosion resistance of copper and/or its alloys in a semiconductor substrate.

In one or more embodiments, the at least one azole compound is in an amount of from at least about 0.001% (e.g., at least about 0.003%, at least about 0.005%, at least about 0.01%, at least about 0.03%, at least about 0.05%, at least about 0.1%, at least about 0.3%, at least about 0.5%, at least about 1%, at least about 1.3%, or at least about 1.5%) by weight to at most about 10% (e.g., at least about 9%, at least about 8%, at least about 7%, at least about 6%, at least about 5%, at least about 4%, at least about 3%, at least about 2.5%, at most about 2.2%, at most about 2%, at most about 1.7%, at most about 1.5%, at most about 1.2%, at most about 1%, at most about 0.7%, at most about 0.5%, at most about 0.2%, at most about 0.15%, at most about 0.1%, at most about 0.07%, or at most about 0.05%) by weight of the polishing compositions described herein. In embodiments where more than one azole compound is included in the polishing composition, the above ranges may apply to each azole compound independently, or to the combined amount of azole compounds within the composition.

In one or more embodiments, the polishing compositions described herein include at least one (e.g., two or three) first amine compound. In one or more embodiments, the first amine compound includes an amino acid having a molecular weight of at most 120 g/mol (e.g., at most 115 g/mol, at most 110 g/mol, at most 105 g/mol, at most 100 g/mol, at most 95 g/mol, or at most 90 g/mol). In one or more embodiments, the at least one first amine compound is selected from the group consisting of proline, glycine, serine, alanine, or mixtures thereof. Without wishing to be bound by theory, it is surprising that the first amine compound can function as a removal rate enhancer for copper.

In one or more embodiments, the at least one first amine compound is in an amount of from at least about 0.001% (e.g., at least about 0.003%, at least about 0.005%, at least about 0.01%, at least about 0.03%, at least about 0.05%, at least about 0.1%, at least about 0.3%, at least about 0.5%, at least about 1%, at least about 1.5%, at least about 2%, at least about 2.5%, at least about 3%, at least about 3.5%, at least about 4%, at least about 4.5%, or at least about 5%) by weight to at most about 18% (e.g., at most about 16.5%, at most about 15%, at most about 12.5%, at most about 10%, at most about 8%, at most about 6%, at most about 5%, at most about 4.5%, at most about 4%, at most about 3.5%, at most about 3%, at most about 2.5%, at most about 2%, at most about 1.5%, at most about 1%, at most about 0.8%, at most about 0.6%, at most about 0.5%, at most about 0.4%, at most about 0.2%, at most about 0.1%, at most about 0.08%, at most about 0.05%, at most about 0.02%, at most about 0.01%, at most about 0.0075%, or at most about 0.005%) by weight of the polishing compositions described herein.

In one or more embodiments, the polishing compositions described herein include at least one (e.g., two or three) second amine compound different from the first amine compound. In one or more embodiments, the second amine compound has a molecular weight of at least 125 g/mol (e.g., at least 130 g/mol, at least 135 g/mol, at least 140 g/mol, at least 145 g/mol, at least 150 g/mol, at least 155 g/mol, at least 160 g/mol, at least 165 g/mol, or at least 170 g/mol). In one or more embodiments, the second amine compound is an amino acid. In one or more embodiments, the second amine compound is an alkylamine. In one or more embodiments, the second amine compound is selected from the group consisting of histidine, phenylalanine, glutamine, aspartic acid, glutamic acid, arginine, tyrosine, (3-aminopropyl)diethanolamine, octylamine, decylamine, dodecylamine, tetradecylamine, pentadecylamine, hexadecylamine, octadecylamine, cyclohexylamine, dicyclohexylamine, adenine, xanthine, thymine, guanine, isoguanine, hypoxanthine or mixtures thereof.

In one or more embodiments, the at least one second amine compound is in an amount of from at least about 0.001% (e.g., at least about 0.003%, at least about 0.005%, at least about 0.01%, at least about 0.03%, at least about 0.05%, at least about 0.1%, at least about 0.3%, at least about 0.5%, at least about 1%, at least about 1.5%, at least about 2%, at least about 2.5%, at least about 3%, at least about 3.5%, at least about 4%, at least about 4.5%, or at least about 5%) by weight to at most about 18% (e.g., at most about 16.5%, at most about 15%, at most about 12.5%, at most about 10%, at most about 8%, at most about 6%, at most about 5%, at most about 4.5%, at most about 4%, at most about 3.5%, at most about 3%, at most about 2.5%, at most about 2%, at most about 1.5%, at most about 1%, at most about 0.8%, at most about 0.6%, at most about 0.5%, at most about 0.4%, at most about 0.2%, at most about 0.1%, at most about 0.08%, at most about 0.05%, at most about 0.02%, at most about 0.01%, at most about 0.0075%, or at most about 0.005%) by weight of the polishing compositions described herein. Without wishing to be bound by theory, it is surprising that the second amine compound described above can significantly decrease molybdenum corrosion (e.g., lower Mo static etch rate) and also reduce the potential for galvanic corrosion at the interface of copper and molybdenum on a substrate.

In one or more embodiments, the polishing compositions described herein can include at least one (e.g., two or three) pH adjustor, if necessary, to adjust the pH to a desired value. In some embodiments, the at least one pH adjustor can be an acid (e.g., an organic or inorganic acid) or a base (e.g., an organic or inorganic base). For example, the pH adjustor can be selected from the group consisting of nitric acid, hydrochloric acid, sulfuric acid, propionic acid, citric acid, malonic acid, hydrobromic acid, hydroiodic acid, perchloric acid, ammonia, ammonium hydroxide, sodium hydroxide, potassium hydroxide, cesium hydroxide, monoethanolamine, diethanolamine, triethanolamine, methylethanolamine, methyldiethanolamine tetrabutylammonium hydroxide, tetrapropylammonium hydroxide, tetraethylammonium hydroxide, tetramethylammonium hydroxide, ethyltrimethylammonium hydroxide, diethyldimethylammonium hydroxide, dimethyldipropylammonium hydroxide, benzyltrimethylammonium hydroxide, tris(2-hydroxyethyl)methylammonium hydroxide, choline hydroxide, and any combinations thereof.

In one or more embodiments, the at least one pH adjuster is in an amount of from at least about 0.001% (e.g., at least about 0.005%, at least about 0.01%, at least about 0.05%, at least about 0.1%, at least about 0.2%, at least about 0.4%, at least about 0.5%, at least about 1% or at least about 1.5%) by weight to at most about 2.5% (e.g., at most about 2%, at most about 1.5%, at most about 1%, at most about 0.5%, at most about 0.1%, or at most about 0.5%) by weight of the polishing compositions described herein.

In one or more embodiments, the polishing compositions described herein can be either acidic or basic. In some embodiments, the polishing compositions can have a pH ranging from at least about 2 to at most about 11. For example, the pH can range from at least about 2 (e.g., at least about 2.5, at least about 3, at least about 3.5, at least about 4, at least about 4.5, or at least about 5) to at most about 11 (e.g., at most about 10.5, at most about 10, at most about 9.5, at most about 9, at most about 8.5, at most about 8, at most about 7.5, at most about 7, at most about 6.5, at most about 6, at most about 5.5, at most about 5, at most about 4.5, or at most about 4). When the polishing compositions are acidic, the pH can range from at least about 3 (e.g., at least about 3.5, at least about 4, at least about 4.5, at least about 5, at least about 5.5, at least about 6, or at least about 6.5) to at most about 7 (e.g., at most about 6.5, at most about 6, at most about 5.5, at most about 5, at most about 4.5, or at most about 4, or at most about 3.5). When the polishing composition are basic, the pH can range from at least about 7.5 (e.g., at least about 8, or at least about 8.5) to at most about 11 (e.g., at most about 10.5, at most about 10, or at most about 9.5).

In one or more embodiments, the polishing compositions described herein can include a solvent (e.g., a primary solvent), such as an aqueous solvent (e.g., water or a solvent including water and an organic solvent). In some embodiments, the solvent (e.g., water) is in an amount of from at least about 10% (e.g., at least about 15 %, at least about 20%, at least about 25%, at least about 30%, at least about 35%, at least about 40%, at least about 45%, at least about 50%, at least about 55%, at least about 60%, at least about 65%, at least about 70%, at least about 75%, at least about 80%, at least about 85%, at least about 90%, at least about 92%, at least about 94%, at least about 95%, or at least about 97%) by weight to at most about 99% (e.g., at most about 98%, at most about 96%, at most about 94%, at most about 92%, at most about 90%, at most about 85%, at most about 80%, at most about 75%, at most about 70%, or at most about 65%) by weight of the polishing compositions described herein.

In one or more embodiments, an optional secondary solvent (e.g., an organic solvent) can be used in the polish compositions (e.g., a POU or concentrated polishing composition) of the present disclosure, which can help with the dissolution of an ingredient (e.g., an azole-containing corrosion inhibitor). In one or more embodiments, the secondary solvent can be one or more alcohols, alkylene glycols, or alkylene glycol ethers. In one or more embodiments, the secondary solvent comprises one or more solvents selected from the group consisting of ethanol, 1-propanol, 2-propanol, n-butanol, propylene glycol, 2-methoxyethanol, 2-ethoxyethanol, propylene glycol propyl ether, and ethylene glycol.

In some embodiments, the secondary solvent is in an amount of from at least about 0.005% (e.g., at least about 0.01%, at least about 0.02%, at least about 0.05%, at least about 0.1%, at least about 0.2%, at least about 0.4%, at least about 0.5%, at least about 0.6%, at least about 0.8%, at least about 1%, at least about 3%, at least about 5%, or at least about 10%) by weight to at most about 15% (e.g., at most about 12%, at most about 10%, at most about 5%, at most about 3%, at most about 2%, at most about 1%, at most about 0.8%, at most about 0.6%, at most about 0.5%, or at most about 0.1%) by weight of the polishing compositions described herein.

In one or more embodiments, the polishing compositions described herein can further include at least one optional additive selected from the group consisting of an oxidizer, a chelating agent, a surfactant, a corrosion inhibitor, and a water-soluble polymer.

The oxidizing agent is not particularly limited, but specific examples thereof include ammonium persulfate, potassium persulfate, hydrogen peroxide, ferric nitrate, diammonium cerium nitrate, iron sulfate, hypochlorous acid, ozone, potassium periodate, and peracetic acid. Without wishing to be bound by theory, it is believed that the oxidizing agent can facilitate the removal of materials during the polishing process.

In some embodiments, the oxidizing agent can be from at least about 0.05% (e.g., at least about 0.1%, at least about 0.2%, at least about 0.3%, at least about 0.4%, at least about 0.5%, at least about 0.6%, at least about 0.7%, at least about 0.8%, at least about 0.9%, at least about 1%, at least about 1.5%, or at least about 2%) to at most about 10% (e.g., at most about 9%, at most about 8%, at most about 7%, at most about 6%, at most about 5%, at most about 4%, at most about 3%, at most about 2%, or at most about 1%) by weight of the polishing compositions described herein.

In one or more embodiments, the chelating agent can be selected from the group consisting of gluconic acid, lactic acid, citric acid, tartaric acid, malic acid, glycolic acid, malonic acid, formic acid, oxalic acid, acetic acid, propionic acid, peracetic acid, succinic acid, lactic acid, amino acetic acid, phenoxyacetic acid, bicine, diglycolic acid, glyceric acid, tricine, alanine, histidine, valine, phenylalanine, proline, glutamine, aspartic acid, glutamic acid, arginine, lysine, tyrosine, benzoic acid, ammonia, 1,2-ethanedisulfonic acid, 4-amino-3-hydroxy-1-naphthalenesulfonic acid, 8-hydroxyquinoline-5-sulfonic acid, aminomethanesulfonic acid, benzenesulfonic acid, hydroxylamine O-sulfonic acid, methanesulfonic acid, m-xylene-4-sulfonic acid, poly(4-styrenesulfonic acid), polyanetholesulfonic acid, p-toluenesulfonic acid, trifluoromethane-sulfonic acid, ethylenediaminetetraacetic acid, diethylenetriaminepentaacetic acid, nitrilotriacetic acid, acetyl acetone, aminotri(methylenephosphonic acid), 1-hydroxyethylidene (1,1-diphosphonic acid), 2-phosphono-1,2,4-butanetricarboxylic acid, hexamethylenediaminetetra(methylenephosphonic acid), ethylenediamine-tetra(methylenephosphonic acid), diethylenetriaminepenta(methylenephosphonic acid), salts thereof, and mixtures thereof. Without wishing to be bound by theory, it is believed that the chelating agent can serve as a removal rate enhancer to facilitate removal of certain materials on a substrate.

In some embodiments, the chelating agent can be from at least about 0.001% (e.g., at least about 0.002%, at least about 0.003%, at least about 0.004%, at least about 0.005%, at least about 0.006%, at least about 0.007%, at least about 0.008%, at least about 0.009%, or at least about 0.01%) to at most about 10% (e.g., at most about 8%, at most about 6%, at most about 5%, at most about 4%, at most about 2%, at most about 1%, at most about 0.8%, at most about 0.6%, or at most about 0.5%) by weight of the polishing compositions described herein.

In one or more embodiments, the polishing compositions described herein can also include one or more surfactants selected from the group consisting of anionic surfactants, non-ionic surfactants, amphoteric surfactants, cationic surfactants, and mixtures thereof.

The cationic surfactant is not particularly limited, but specific examples thereof include aliphatic amine salts and aliphatic ammonium salts.

The non-ionic surfactant is not particularly limited, but specific examples thereof include an ether-type surfactant, an ether ester-type surfactant, an ester-type surfactant, and an acetylene-based surfactant. The ether-type surfactant is not particularly limited, but specific examples thereof include polyethylene glycol mono-4-nonylphenyl ether, polyethylene glycol monooleyl ether, and triethylene glycol monododecyl ether. The ether ester-type surfactant is not particularly limited, but a specific example thereof is a polyoxyethylene ether of a glycerin ester. The ester-type surfactant is not particularly limited, but specific examples thereof include a polyethylene glycol fatty acid ester, a glycerin ester, and a sorbitan ester. The acetylene-based surfactant is not particularly limited, but specific examples thereof include ethylene oxide adducts of acetylene alcohol, acetylene glycol, and acetylene diol.

The amphoteric surfactant is not particularly limited, but specific examples thereof include betaine-based surfactants.

The anionic surfactant is not particularly limited, but specific examples thereof include carboxylic acid salts, sulfonic acid salts, sulfate salts, and phosphate salts. The carboxylic acid salts are not particularly limited, but specific examples thereof include fatty acid salts (e.g., soaps) and alkyl ether carboxylic acid salts. Examples of the sulfonic acid salts include alkylbenzenesulfonic acid salts, alkylnaphthalenesulfonic acid salts, and a-olefin sulfonic acid salts. The sulfate salts are not particularly limited, but specific examples thereof include higher alcohol sulfate salts and alkyl sulfate salts. The phosphates are not particularly limited, but specific examples thereof include alkyl phosphates and alkyl ester phosphates.

The corrosion inhibitor is not particularly limited, but specific examples thereof include choline hydroxide, amino alcohols (e.g., monoethanolamine and 3-amino-4-octanol), ethylenediaminetetra(methylenephosphonic acid), and mixtures thereof.

The water-soluble polymer is not particularly limited, but specific examples thereof include polyacrylamide, polyvinyl alcohol, polyvinylpyrrolidone, polyacrylic acid, hydroxyethyl cellulose, and copolymers that include the polymers previously listed. Without wishing to be bound by theory, it is believed that the water-soluble polymer can serve as a removal rate inhibitor to reduce the removal rate of certain exposed materials on a substrate that do not intend to be removed or should be removed at a lower removal rate during the polishing process.

In one or more embodiments, the water-soluble polymer can be from at least about 0.01% (e.g., at least about 0.02%, at least about 0.03%, at least about 0.04%, at least about 0.05%, at least about 0.06%, at least about 0.07%, at least about 0.08%, at least about 0.09%, or at least about 0.1%) to at most about 1% (e.g., at most about 0.8%, at most about 0.6%, at most about 0.5%, at most about 0.4%, at most about 0.2%, at most about 0.1%, at most about 0.08%, at most about 0.06%, or at most about 0.05%) by weight of the polishing compositions described herein.

In one or more embodiments, the polishing composition described herein can be substantially free of one or more of certain ingredients, such as organic solvents, pH adjusting agents, quaternary ammonium compounds (e.g., salts such as tetraalkylammonium salts and hydroxides such as tetramethylammonium hydroxide), alkali bases (such as alkali hydroxides), fluorine-containing compounds (e.g., fluoride compounds or fluorinated compounds (such as fluorinated polymers/surfactants)), silicon-containing compounds such as silanes (e.g., alkoxysilanes), nitrogen containing compounds (e.g., amino acids, amines, or imines (e.g., amidines such as 1,8-diazabicyclo[5.4.0]-7-undecene (DBU) and 1,5-diazabicyclo[4.3.0]non-5-ene (DBN))), salts (e.g., halide salts or metal salts), polymers (e.g., non-ionic, cationic, or anionic polymers), inorganic acids (e.g., hydrochloric acid, sulfuric acid, phosphoric acid, or nitric acid), surfactants (e.g., cationic surfactants, anionic surfactants, or non-ionic surfactants), plasticizers, oxidizing agents (e.g., hydrogen peroxide and periodic acid), corrosion inhibitors (e.g., azole or non-azole corrosion inhibitors), electrolytes (e.g., polyelectrolytes), and/or certain abrasives (e.g., ceria abrasives, non-ionic abrasives, surface modified abrasives , negatively/positively charged abrasives, or ceramic abrasive composites). The halide salts that can be excluded from the polishing compositions include alkali metal halides (e.g., sodium halides or potassium halides) or ammonium halides (e.g., ammonium chloride), and can be fluorides, chlorides, bromides, or iodides. As used herein, an ingredient that is “substantially free” from a polishing composition refers to an ingredient that is not intentionally added into the polishing composition. In some embodiments, the polishing composition described herein can have at most about 1000 ppm (e.g., at most about 500 ppm, at most about 250 ppm, at most about 100 ppm, at most about 50 ppm, at most about 10 ppm, or at most about 1 ppm) of one or more of the above ingredients that are substantially free from the polishing composition. In some embodiments, the polishing compositions described herein can be completely free of one or more of the above ingredients.

In one or more embodiments, the polishing compositions described herein can have a ratio (i.e., a removal rate ratio or selectivity) of a removal rate for copper and/or its alloys to a removal rate for molybdenum and/or its alloys of from at least about 10:1 (e.g., at least about 15:1, at least about 20:1, at least about 25:1, at least about 30:1, at least about 35:1, at least about 40:1, at least about 45:1, at least about 50:1, at least about 55:1, at least about 60:1, at least about 65:1, or at least about 70:1) to at most about 1000:1 (e.g., or at most about 500:1). In one or more embodiments, the ratios described above can be applicable when measuring removal rates for polishing either blanket wafers or patterned wafers (e.g., wafers including conductive layers, barrier layers, and/or dielectric layers) when the blanket or patterned wafers have the copper and molybdenum materials deposited via physical vapor deposition (PVD), atomic layer deposition (ALD), or (CVD). However, it is to be understood that the method of depositing the copper and molybdenum materials may have an impact on their removal rates and therefore the selectivity ratio achieved. For example, it is known that PVD films have a higher degree of vacancies and non-uniformity within the films, rendering them relatively easier to remove than ALD or CVD films.

In one or more embodiments, the polishing compositions described herein can have a minimum copper removal rate (whether on blanket wafers or on patterned wafers) of about 1000 Å/min, or about 1250 Å/min, or about 1500 Å/min, or about 1750 Å/min, or about 2000 Å/min, or about 2250 A/min, or about 2500 A/min, when the polishing is performed at a downforce of about 1.5 psi. In one or more embodiments, the polishing compositions described herein can have a maximum molybdenum removal rate (whether on blanket wafers or on patterned wafers) of about 1000 Å/min, or about 750 Å/min, or about 500 Å/min, or about 250 Å/min, or about 100 Å/min, or about 50 Å/min, or about 35 A/min when the polishing is performed at a downforce of about 1.5 psi. The removal rates described above for copper and molybdenum may be for any of physical vapor deposition (PVD), atomic layer deposition (ALD), or chemical vapor deposition (CVD) deposited films.

In one or more embodiments, this disclosure features a method of polishing that can include applying a polishing composition according to the present disclosure to a substrate (e.g., a wafer); and bringing a pad (e.g., a polishing pad) into contact with the surface of the substrate and moving the pad in relation to the substrate. In one or more embodiments, the substrate can include at least one of silicon oxides (e.g., tetraethyl orthosilicate (TEOS), high density plasma oxide (HDP), high aspect ratio process oxide (HARP), or borophosphosilicate glass (BPSG)), spin on films (e.g., films based on inorganic particle or films based on cross-linkable carbon polymer), silicon nitride, silicon carbide, high-K dielectrics (e.g., metal oxides of hafnium, aluminum, or zirconium), silicon (e.g., polysilicon, single crystalline silicon, or amorphous silicon), carbon, metals (e.g., tungsten, copper, cobalt, ruthenium, molybdenum, titanium, tantalum, or aluminum) or alloys thereof, metal nitrides (e.g., titanium nitride or tantalum nitride), and mixtures or combinations thereof. In one or more embodiments, the polishing method can include applying a polishing composition described herein to a substrate (e.g., a wafer) containing copper and molybdenum and/or its alloys on a surface of the substrate.

In one or more embodiments, the method that uses a polishing composition described herein can further include producing a semiconductor device from the substrate treated by the polishing composition through one or more steps. For example, photolithography, ion implantation, dry/wet etching, plasma etching, deposition (e.g., PVD, CVD, ALD, ECD), wafer mounting, die cutting, packaging, and testing can be used to produce a semiconductor device from the substrate treated by the polishing composition described herein.

The specific examples below are to be construed as merely illustrative, and not limitative of the remainder of the disclosure in any way whatsoever. Without further elaboration, it is believed that one skilled in the art can, based on the description herein, utilize the present invention to its fullest extent.

### EXAMPLES

In these examples, the polishing was performed on 300 mm wafers using an AMAT Reflexion LK CMP polisher with a soft pad and a polishing composition flow rate between about 200 and 500 mL/min or on 200 mm wafers using a Mirra polisher, a Fujibo H800 or H804 pad and a flow rate between about 200 and 500 ml/min flow rate.

The general compositions used in the examples are shown in Table 1 below. The specific details on the differences in the compositions tested will be explained in further detail when discussing the respective examples.

Table 1

| Component | % By Weight of the Composition |
|---|---|
| pH adjuster (base) | 0.005 - 1 |
| Azole Compound | 0.001 - 3 |
| First amine (MW < 120 g/mol) | 0.001 - 3 (if used) |
| Second amine (MW > 125 g/mol) | 0.001 - 2 (if used) |
| Organic Solvent | 0.001 - 1 |
| Abrasive (silica) | 0.1-5 |
| Oxidizer | 0.1-5 |
| Solvent (DI Water) | 75-99 |
| pH | 4-8 |

In the below examples, the first amine compound is selected from the group consisting of proline, glycine, serine, alanine, or mixtures thereof. In the below examples, the second amine is selected from the group consisting of histidine, phenylalanine, glutamine, aspartic acid, glutamic acid, arginine, tyrosine, carnosine, (3-aminopropyl)diethanolamine, octylamine, decylamine, dodecylamine, tetradecylamine, pentadecylamine, hexadecylamine, octadecylamine, cyclohexylamine, dicyclohexylamine, adenine, xanthine, thymine, guanine, isoguanine, hypoxanthine, or mixtures thereof.

### Example 1

The Static Etch Rate (SER) for molybdenum was measured by suspending molybdenum coupons in Compositions 1-4 at 45° C. for one minute, and the molybdenum/copper removal rate (RR) was measured by polishing blanket wafers with Compositions 1-4. The Cu blanket films were electroplated and the Mo blanket films were deposited by PVD. Compositions 1-4 were identical except that (1) Composition 1 was a control and did include the first amine compound, but did not include the second amine compound listed in Table 1 above, and (2) Compositions 2-4 included a second amine compound, where the second amine compound used in Compositions 2-4 are distinct from each other. Compositions 2-3 included an amino acid as the second amine compound, while Composition 4 included an alkylamine compound as the second amine compound. Compositions 2-4 included the same amount and type of first amine compound as Composition 1. The test results are summarized in Table 2 below.

Table 2

| | Comp. 1 | Comp. 2 | Comp. 3 | Comp. 4 |
|---|---|---|---|---|
| Mo SER (Å/min) | 356 | 17 | 38 | 16 |
| Cu RR (Å/min) | 3377 | 3419 | 3745 | 3737 |
| Mo RR (Å/min) | 829 | 133 | 198 | 398 |
| Cu/Mo RR Ratio | 4.07 | 25.7 | 18.9 | 9.38 |

The results show that the addition of the second amine compound effectively reduced the molybdenum static etch rate and the molybdenum removal rate, while slightly increasing the copper removal rate. The combination of these aspects leads to significantly increased Cu/Mo polishing rate ratio for Compositions 2-4. These results suggest that a second amine compound, as defined in this disclosure, can be used as a corrosion inhibitor for Mo during a CMP process.

### Example 2

The molybdenum and copper removal rates (RR) were measured by polishing blanket wafers with Compositions 5-6. The copper blanket films were electrodeposited and the molybdenum blanket films were deposited by ALD. Compositions 5-6 were identical except that Composition 5 was a control and included the first amine compound, but did not include the second amine compound listed in Table 1 above, while Composition 6 included both the first and second amine compound. The second amine compound used in Composition 6 is an amino acid. The test results are summarized in Table 3 below.

Table 3

| | Comp. 5 | Comp. 6 |
|---|---|---|
| Cu RR (Å/min) | 2952 | 2603 |
| Mo RR (Å/min) | 73 | 38 |
| Cu/Mo Ratio | 40.4 | 68.5 |

The results show that, similar to Example 1, the inclusion of the second amine compound reduced the removal rate of molybdenum and thereby increased the Cu/Mo polishing rate ratio.

### Example 3

Tafel plot current intersections can be a good indicator of the potential for galvanic corrosion occurring during polishing at the junction of two metals (e.g., the Cu/Mo intersection). The Tafel scans were performed in Compositions 7-10 by measuring the current as the voltage is scanned from low to high at a rate of 1 mV/s in the range of +/- 0.25 V relative to the open circuit voltage. The target metal (e.g., Cu or Mo) is used as the working electrode, graphite as the counter electrode, and a saturated calomel electrode (SCE) as the reference electrode. Compositions 7-10 were identical except that (1) Composition 7 was a control and included the first amine compound, but did not include the second amine compound listed in Table 1 above, and (2) Compositions 8-10 included a second amine compound, where the second amine compounds used in Compositions 8-10 are distinct from each other. Compositions 8-9 included an amino acid as the second amine compound, while Composition 10 included an alkylamine compound as the second amine compound. Compositions 8-10 also included the same amount and type of first amine compound as Composition 7. The current intersections from Tafel plots are shown in Table 4 below.

Table 4

| | Comp. 7 | Comp. 8 | Comp. 9 | Comp. 10 |
|---|---|---|---|---|
| Current Intersection (µA) | 20.9 | 17 | 16.5 | 20.2 |

The results show that Compositions 8-10, with the second amine compound, have a lower current intersection when compared with Composition 7, without the second amine compound. This indicates that the propensity for galvanic corrosion is lower when the polishing composition includes a second amine compound as described in the present disclosure.

### Example 4

The molybdenum and copper removal rates (RR) were measured by polishing blanket wafers with Compositions 11-16. The Cu blanket films were electroplated and the Mo blanket films were deposited by PVD. The compositions were the same except for the differences indicated in Table 5 below. Composition 11 includes only a single first amine compound and no second amine compound. Compositions 13-16 include only a single second amine compound. Compositions 13 and 15 include the same alkylamine as the second amine compound. Compositions 14 and 16 include the same amino acid as the second amine compound, which is a different second amine compound than that used in Compositions 13 and 15. Composition 12 includes both of the second amine compounds used in Compositions 13-16 (i.e., two distinct second amine compounds with one being an amino acid and the other being an alkylamine). The same first amine compound is used in Compositions 11-12 and 15-16.

Table 5

| | Comp. 11 | Comp. 12 | Comp. 13 | Comp. 14 | Comp. 15 | Comp. 16 |
|---|---|---|---|---|---|---|
| First Amine Compound | Yes | Yes | No | No | Yes | Yes |
| Second Amine Compound | No | Yes | Yes | Yes | Yes | Yes |
| CuRR (Å/min) | 3624 | 2888 | 602 | 1441 | 3493 | 2868 |
| Mo RR (Å/min) | 716 | 94 | 321 | 161 | 120 | 175 |
| Cu/Mo Ratio | 5.1 | 30.4 | 1.9 | 8.9 | 29 | 16.4 |

The results demonstrate that there is a unique synergism that results from using both a first amine compound and a second amine compound, both as described in this disclosure, in a polishing composition on a substrate that includes copper and molybdenum. Specifically, without any second amine compound (Comp. 11) the Mo RR is highly elevated and results in a low Cu/Mo removal rate ratio. Conversely, without the first amine compound (Comps. 13-14) the Cu removal rate plummets to an unacceptable level, while the Mo RR still remains elevated resulting in a low Cu/Mo removal rate ratio. Significantly, the compositions that include both the first and the second amine compounds (Comps. 12 and 15-16) maintain a high Cu RR and achieve a low Mo RR, which leads to a highly desirable high Cu/Mo removal rate ratio. Composition 15 surprisingly significantly decreased the Mo removal rate when compared with Composition 13, even though the presence of the first amine compound is primarily used to increase the Cu removal rate.

The present disclosure uses the term “not particularly limited” several times throughout. While this indicates that a number of stated members of a chemical class (e.g. azoles) may be suitable for a particular use, it does not mean that any particular member of that chemical class cannot be particularly advantageous or preferred.

While this disclosure has been described with respect to the examples set forth herein, it is understood that other modifications and variations are possible without departing from the spirit and scope of the disclosure as defined in the appended claims.

1. A polishing composition, comprising:
at least one abrasive;
at least one azole compound;
at least one first amine compound, the at least one first amine compound comprising an
amino acid having a molecular weight of at most 120 g/mol; at least one second amine compound having a molecular weight of at least 125 g/mol; and
an aqueous solvent.

2. The polishing composition of claim 1, wherein the at least one abrasive is selected from the group consisting of alumina, silica, titania, ceria, zirconia, co-formed products of alumina, silica, titania, ceria, or zirconia, coated abrasives, surface modified abrasives, and mixtures thereof.

3. The polishing composition of claim 1, wherein the at least one abrasive is present in an amount of from about 0.01% to about 50% by weight of the composition.

4. The polishing composition of claim 1, wherein the azole is selected from the group consisting of heterocyclic azoles, substituted or unsubstituted triazoles, substituted or unsubstituted tetrazoles, substituted or unsubstituted diazoles, and substituted or unsubstituted benzothiazoles.

5. The polishing composition of claim 1, wherein the azole is selected from the group consisting of tetrazole, benzotriazole, tolyltriazole, methyl benzotriazole, ethyl benzotriazole, propyl benzotriazole, butyl benzotriazole, pentyl benzotriazole, hexyl benzotriazole, 5,6-dimethyl benzotriazole, chloro benzotriazole, 5,6-dichloro benzotriazole, 1-(chloromethyl)-1-H-benzotriazole, chloroethyl benzotriazole, phenyl benzotriazole, benzyl benzotriazole, aminotriazole, aminobenzimidazole, pyrazole, imidazole, aminotetrazole, adenine, benzimidazole, thiabendazole, 1,2,3-triazole, 1,2,4-triazole, 1-hydroxybenzotriazole, 2-methylbenzothiazole, 2-aminobenzimidazole, 2-amino-5-ethyl-1,3,4-thiadiazole, 3,5-diamino-1,2,4-triazole, 3-amino-5-methylpyrazole, 4-amino-4H -1 ,2,4-triazole.

6. The polishing composition of claim 1, wherein the at least one azole is present in an amount of from about 0.001% to about 10% by weight of the composition.

7. The polishing composition of claim 1, wherein the at least one first amine compound is selected from the group consisting of proline, glycine, serine, alanine, or mixtures thereof.

8. The polishing composition of claim 1, wherein the at least one first amine compound is present in an amount of from about 0.001% to about 18% by weight of the composition.

9. The polishing composition of claim 1, wherein the at least one second amine compound is an amino acid.

10. The polishing composition of claim 1, wherein the at least one second amine compound is an alkylamine.

11. The polishing composition of claim 1, wherein the at least one second amine compound is selected from the group consisting of histidine, phenylalanine, glutamine, aspartic acid, glutamic acid, arginine, tyrosine, carnosine, (3-aminopropyl)diethanolamine, octylamine, decylamine, dodecylamine, tetradecylamine, pentadecylamine, hexadecylamine, octadecylamine, cyclohexylamine, dicyclohexylamine, adenine, xanthine, thymine, guanine, isoguanine, hypoxanthine, or mixtures thereof.

12. The polishing composition of claim 1, wherein the at least one second amine compound is present in an amount from about 0.001% to about 18% by weight of the composition.

13. The polishing composition of claim 1, wherein the composition has a pH ranging from about 2 to about 10.

14. The polishing composition of claim 1, wherein the composition exhibits a Cu:Mo polishing selectivity ratio of at least 10:1 for films deposited by physical vapor deposition.

15. A method, comprising:
applying the polishing composition of claim 1to a substrate comprising at least one of copper, molybdenum, an alloy of copper, an alloy of molybdenum, and any combinations thereof, on a surface of the substrate; and
bringing a pad into contact with the surface of the substrate and moving the pad in relation to the substrate.

16. The method of claim 15, further comprising forming a semiconductor device from the substrate.

17. The method of claim 16, wherein the surface of the substrate comprises copper and molybdenum deposited by physical vapor deposition; and
wherein the copper and molybdenum are polished at a selectivity ratio of at least 10:1.
